(19) United States
(12) Patent Application Publication
(10) Pub. No.: US 2016/0073553 A1
(43) Pub. Date: Mar. 10, 2016

(54) HEAT DISSIPATION STRUCTURE OF HANDHELD DEVICE

(71) Applicant: Asia Vital Components Co., Ltd., New Taipei City (TW)

(72) Inventor: Kuei-Feng Chiang, New Taipei City (TW)

(21) Appl. No.: 14/477,876

(22) Filed: Sep. 5, 2014

(51) Int. Cl. H05K 7/20; G06F 1/20

(52) U.S. Cl. CPC H05K 7/20427; G06F 1/203

(57) ABSTRACT

A heat dissipation structure of handheld device includes a carrier body. The carrier body has a first receiving space. The first receiving space has a heat absorption section and a heat dissipation section. The heat dissipation section is adjacent to the heat absorption section and formed with a heat dissipation layer. The heat absorption section is able to quickly absorb the heat generated by the electronic components carried by the carrier body and transfer the heat to the heat dissipation layer of the heat dissipation section so as to quickly dissipate the heat.

### BACKGROUND OF THE INVENTION

1. Field of the Invention

The present invention relates generally to a heat dissipation structure of handheld device, and more particularly to a heat dissipation structure of handheld device, which has higher heat dissipation effect.

2. Description of the Related Art

Currently, there are various mobile devices such as thin-type notebook, tablet and intelligent mobile phone. The internal calculation execution units of the mobile devices have higher and higher operation speed. As a result, the heat generated by these units is greatly increased. In consideration of convenient carriage, these mobile devices have become thinner and thinner. Also, in order to prevent alien article and moisture from entering the interior of the mobile device, the mobile device is generally simply formed with earphone port or connector port without any other opening in communication with ambient air. Therefore, convection can hardly take place between the internal air of the mobile device and the ambient air. Due to the inherent factor of thinned design, the heat generated by the internal calculation execution units and battery of the mobile device can be hardly quickly dissipated outward. Moreover, the internal space of the mobile device is a closed space so that convection is very hard to take place. Under such circumstance, the heat can be hardly dissipated. As a result, the heat will accumulate within the mobile device. This will seriously deteriorate the working efficiency of the mobile device or even lead to thermal shutdown of the mobile device.

Furthermore, in order to solve the above problems, some manufacturers arrange passive heat dissipation elements inside the mobile device, such as heat plate, vapor chamber and heat sink to dissipate the heat. However, still due to the thinned design of the mobile device, the internal space of the mobile device is so narrow that the heat dissipation elements arranged in the space are limited to have an ultrathin thickness for arrangement in the narrow internal space. Due to the limitation of size and thickness, the internal capillary structures and vapor passages of the heat plate and vapor chamber must be very thin. Under such circumstance, as a whole, the heat conduction efficiency of the heat plate and vapor chamber is inevitably detracted. As a result, the heat dissipation performance can be hardly enhanced. In case that the power of the internal calculation unit of the mobile device is too high, the conventional heat plate and vapor chamber will be unable to effectively dissipate the heat generated by the calculation unit. Therefore, it has become a critical issue in this field how to arrange effective heat dissipation elements in the narrow closed space of the mobile device to effectively dissipate the heat.

In addition, the first receiving space in the handheld device is quite narrow and the internal electronic components of the handheld device are compactly stacked. Therefore, it is hard to transfer the heat generated by the electronic components to outer side to dissipate the heat. As a result, the heat is likely to accumulate in the first receiving space of the handheld device. Therefore, it is also a critical issue in this field how to effectively dissipate the heat of the handheld device.

### SUMMARY OF THE INVENTION

It is therefore a primary object of the present invention to provide a heat dissipation structure of handheld device. The heat dissipation structure includes a carrier body. The carrier body has a first receiving space. The first receiving space has a heat absorption section and a heat dissipation section. The heat dissipation section is formed with a heat dissipation layer.

The heat absorption section is able to quickly absorb the heat generated by the electronic components received in the first receiving space of the carrier body and transfer the heat to the heat dissipation layer of the heat dissipation section so as to quickly dissipate the heat. The heat dissipation structure of handheld device has higher heat dissipation efficiency.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein:

FIG. 1 is a perspective exploded view of a first embodiment of the heat dissipation structure of handheld device of the present invention;

FIG. 2 is a sectional assembled view of the first embodiment of the heat dissipation structure of handheld device of the present invention;

FIG. 3 is a perspective exploded view of a second embodiment of the heat dissipation structure of handheld device of the present invention;

FIG. 4 is a sectional assembled view of the second embodiment of the heat dissipation structure of handheld device of the present invention;

FIG. 5 is a perspective exploded view of a third embodiment of the heat dissipation structure of handheld device of the present invention;

FIG. 6 is a sectional assembled view of the third embodiment of the heat dissipation structure of handheld device of the present invention;

FIG. 7 is a perspective exploded view of a fourth embodiment of the heat dissipation structure of handheld device of the present invention;

FIG. 8 is a sectional assembled view of the fourth embodiment of the heat dissipation structure of handheld device of the present invention;

FIG. 9 is a perspective exploded view of a fifth embodiment of the heat dissipation structure of handheld device of the present invention; and

FIG. 10 is a sectional assembled view of the fifth embodiment of the heat dissipation structure of handheld device of the present invention.

### DETAILED DESCRIPTION OF THE PREFERRED EMBODIMENTS

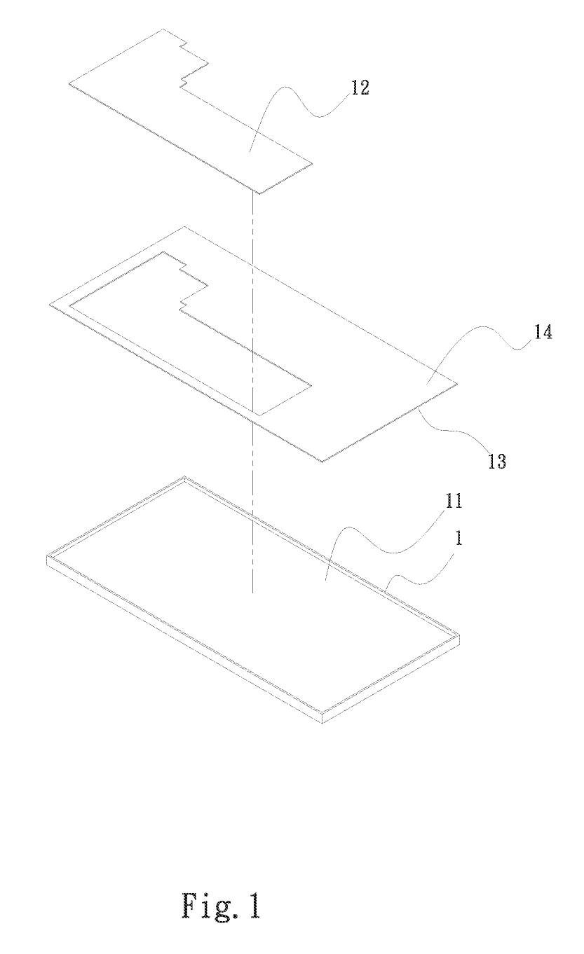

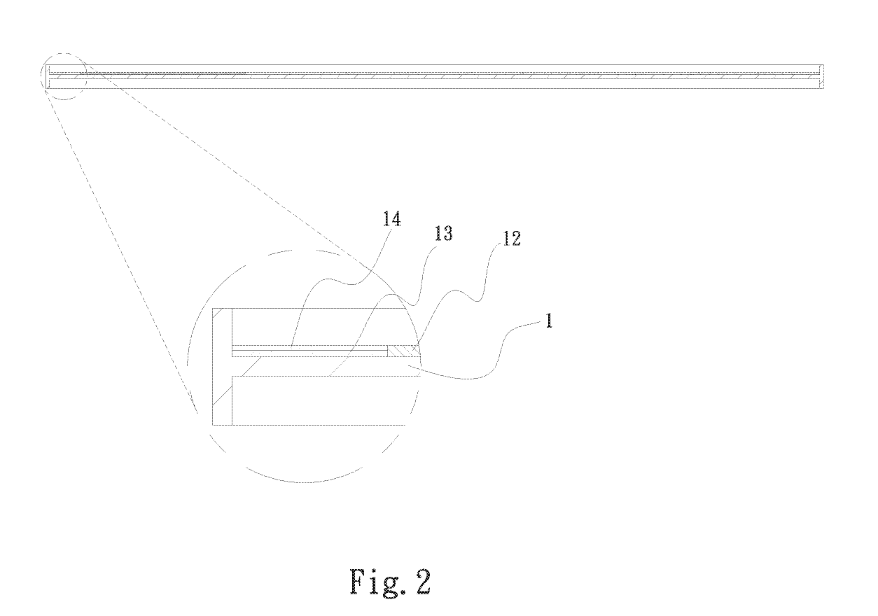

Please refer to FIGS. 1 and 2. FIG. 1 is a perspective exploded view of a first embodiment of the heat dissipation structure of handheld device of the present invention. FIG. 2 is a sectional assembled view of the first embodiment of the heat dissipation structure of handheld device of the present invention. According to the first embodiment, the heat dissipation structure of handheld device of the present invention includes a carrier body 1.

The carrier body 1 has a first receiving space 11. The first receiving space 11 has a heat absorption section 12 and a heat dissipation section 13. The heat dissipation section 13 is adjacent to the heat absorption section 12 and is formed with a heat dissipation layer 14.

In this embodiment, the heat dissipation section 13 and the heat absorption section 12 are disposed in the first receiving space 11 on the same side and the heat dissipation section 13 is disposed outside the heat absorption section 12.

The carrier body 1 is made of metal or nonmetal material. In this embodiment, the carrier body 1 is, but not limited to, made of metal material. The metal material is a stainless steel board body.

The heat dissipation layer 14 is formed by means of micro-arc oxidation (MAO), plasma electrolytic oxidation (PEO), anodic spark deposition (ASD) or anodic oxidation by spark deposition (ANOF). The heat dissipation layer 14 is made of a high-thermal-conductivity material selected from a group consisting of ceramic material, graphite material, copper material, aluminum material and the likes.

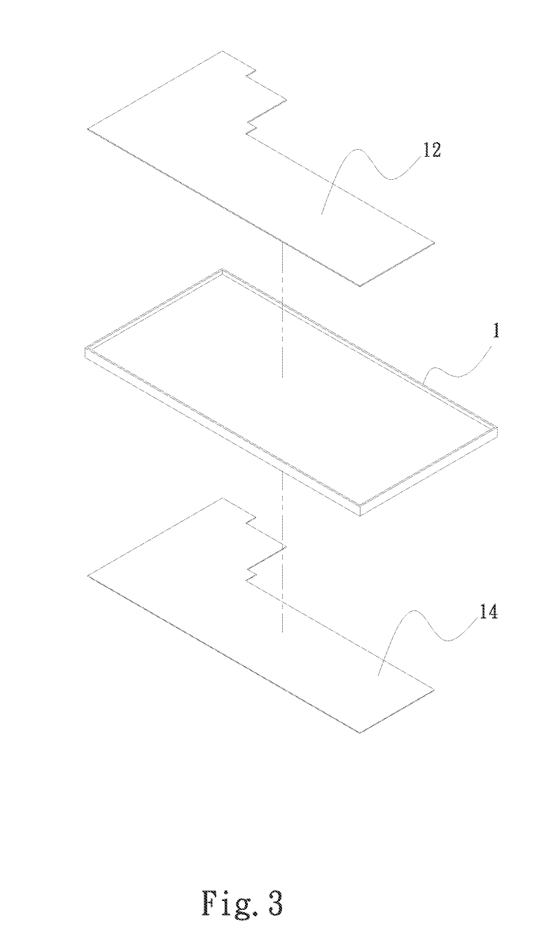

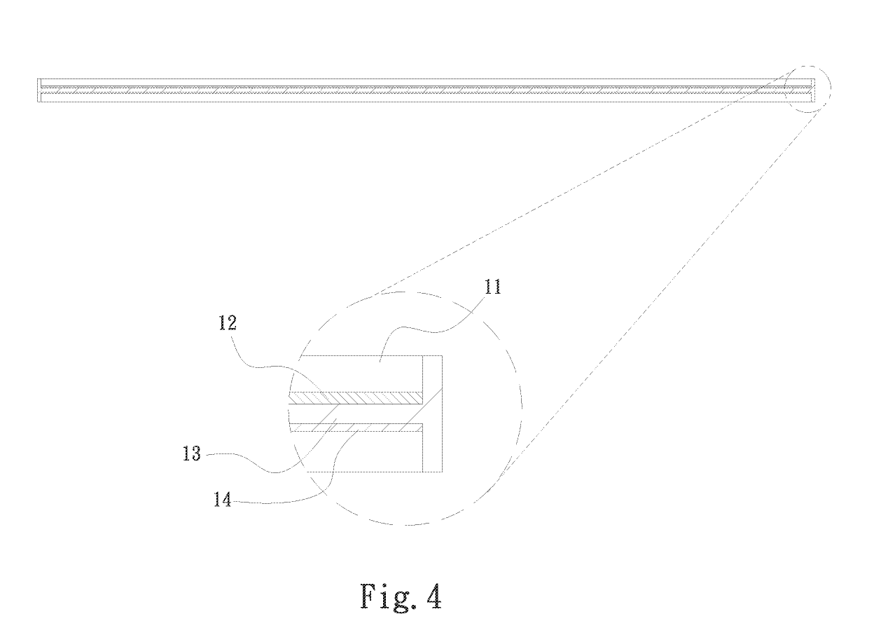

Please now refer to FIGS. 3 and 4. FIG. 3 is a perspective exploded view of a second embodiment of the heat dissipation structure of handheld device of the present invention. FIG. 4 is a sectional assembled view of the second embodiment of the heat dissipation structure of handheld device of the present invention. The second embodiment is partially identical to the first embodiment in structure and thus will not be repeatedly described. The second embodiment is different from the first embodiment in that the heat dissipation section 13 is disposed on one side of the carrier body 1 opposite to the heat absorption section 12. That is, the heat dissipation section 13 and the heat absorption section 12 are respectively disposed on two sides of the carrier body 1.

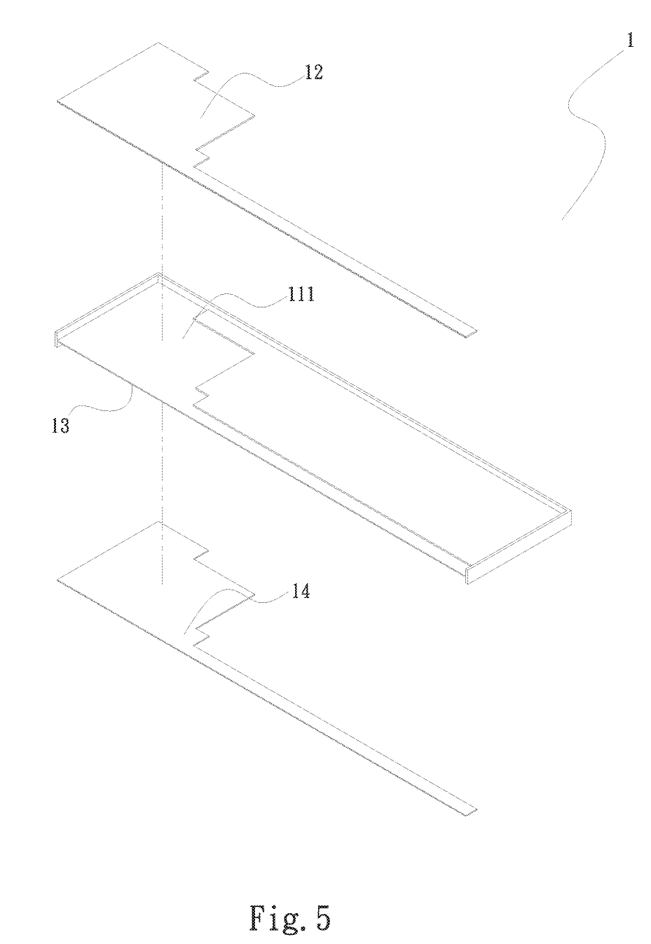

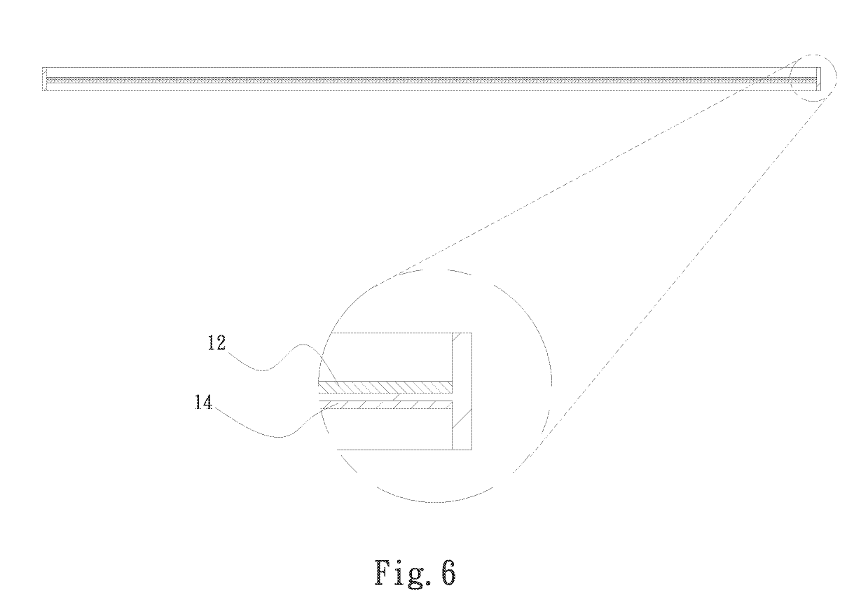

Please now refer to FIGS. 5 and 6. FIG. 5 is a perspective exploded view of a third embodiment of the heat dissipation structure of handheld device of the present invention. FIG. 6 is a sectional assembled view of the third embodiment of the heat dissipation structure of handheld device of the present invention. The third embodiment is partially identical to the first embodiment in structure and thus will not be repeatedly described. The third embodiment is different from the first embodiment in that the heat absorption section 12 is a heat conductor with good thermal conductivity. The heat absorption section 12 is disposed on the carrier body 1. The carrier body 111 is formed with a recess 111 in which the heat absorption section 12 is inlaid. The heat dissipation section 13 is correspondingly disposed on the other side of the recess 111. The heat dissipation layer 14 is formed on the heat dissipation section 13.

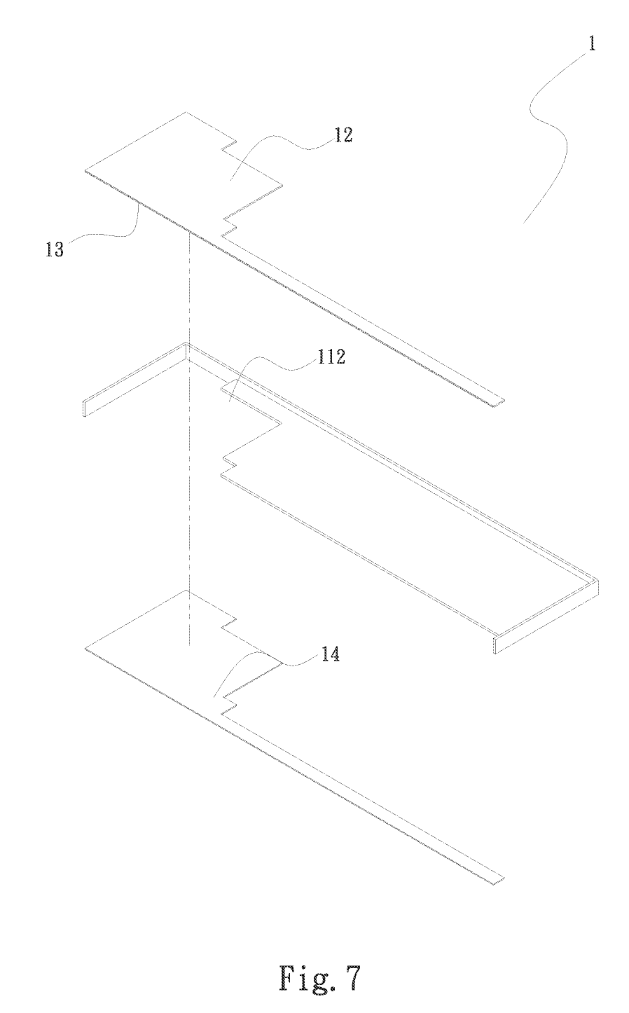

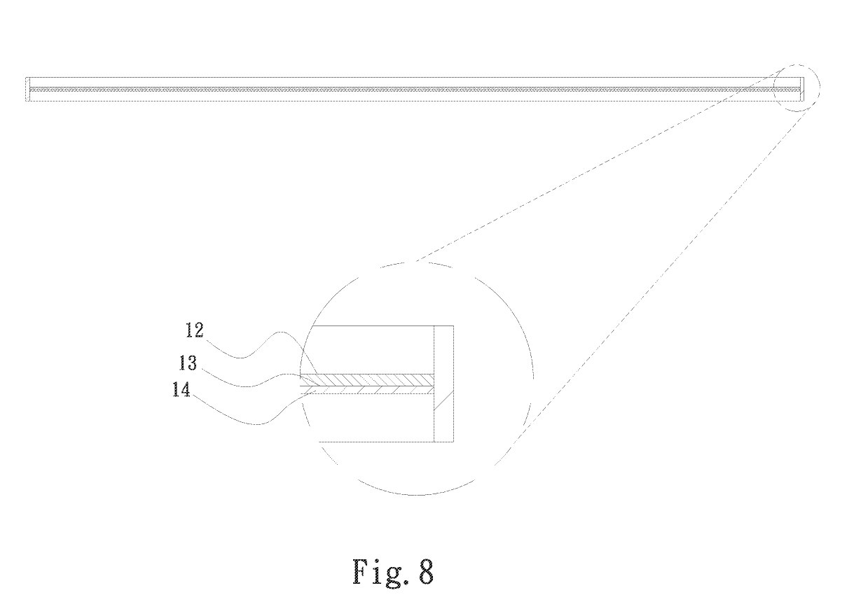

Please now refer to FIGS. 7 and 8. FIG. 7 is a perspective exploded view of a fourth embodiment of the heat dissipation structure of handheld device of the present invention. FIG. 8 is a sectional assembled view of the fourth embodiment of the heat dissipation structure of handheld device of the present invention. The fourth embodiment is partially identical to the first embodiment in structure and thus will not be repeatedly described. The fourth embodiment is different from the first embodiment in that the heat absorption section 12 is a heat conductor with good thermal conductivity. The carrier body 1 is formed with a perforation 112 in which the heat absorption section 12 is inlaid. The heat dissipation section 13 is disposed on the other side corresponding to the heat absorption section 12. The heat dissipation layer 14 is formed on the heat dissipation section 13. The heat conductor with good thermal conductivity is selected from a group consisting of copper, aluminum and the likes. The heat absorption section 12 and the heat dissipation layer 14 are respectively flush with two lateral planes of the carrier body 1.

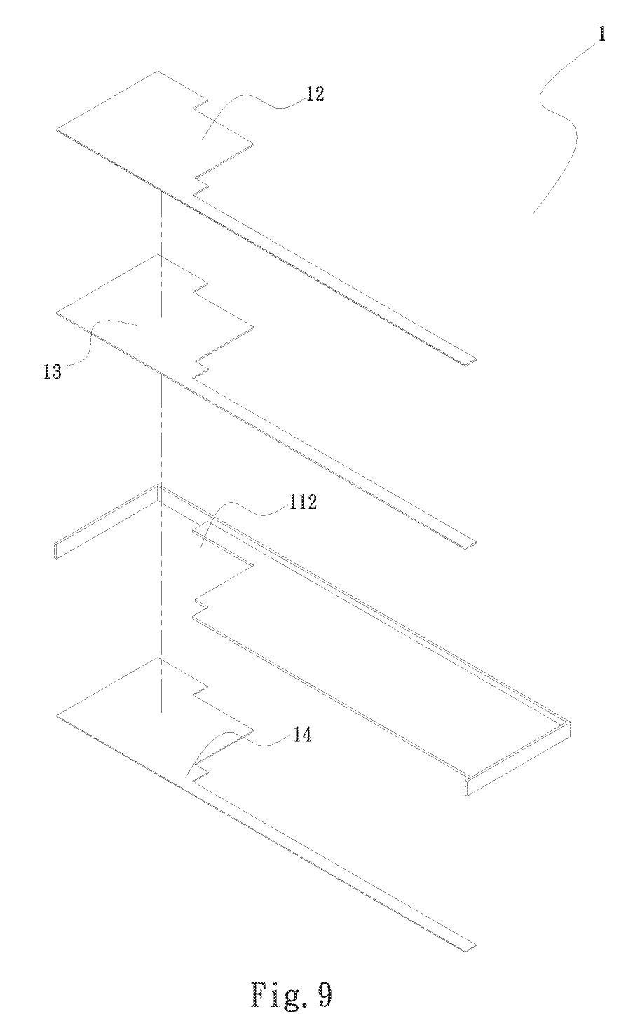

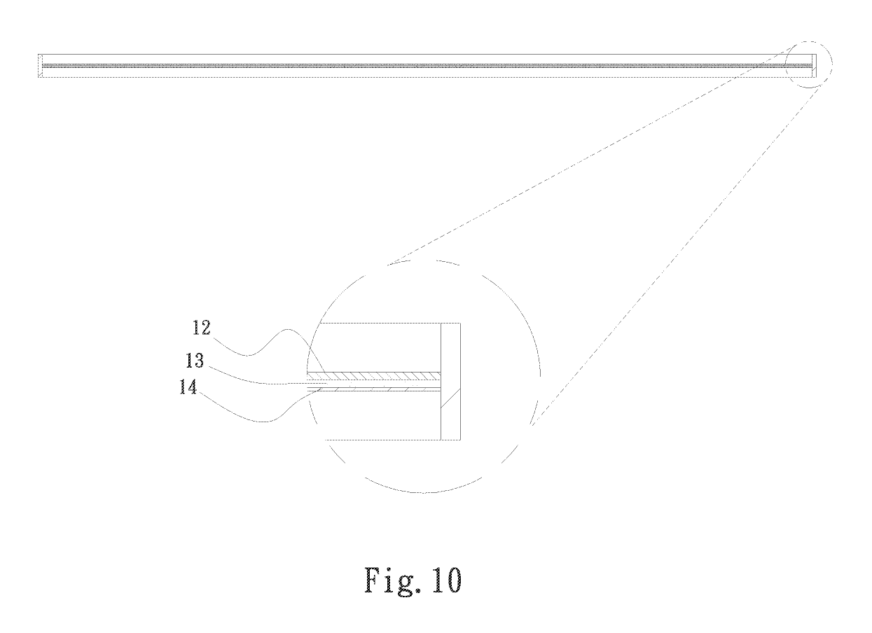

Please now refer to FIGS. 9 and 10. FIG. 9 is a perspective exploded view of a fifth embodiment of the heat dissipation structure of handheld device of the present invention. FIG. 10 is a sectional assembled view of the fifth embodiment of the heat dissipation structure of handheld device of the present invention. The fifth embodiment is partially identical to the first embodiment in structure and thus will not be repeatedly described. The fifth embodiment is different from the first embodiment in that the heat absorption section 12 and the heat dissipation section 13 are heat conductors with good thermal conductivity. The carrier body 1 is formed with a perforation 112 in which the heat absorption section 12 is inlaid. The heat dissipation section 13 is disposed on the other side corresponding to the heat absorption section 12. The heat dissipation layer 14 is formed on the heat dissipation section 13. The heat conductors with good thermal conductivity are selected from a group consisting of copper, aluminum and the likes. In this embodiment, the heat absorption section 12 is made of copper material, while the heat dissipation section 13 is made of aluminum material. The heat absorption section 12 and the heat dissipation section 13 are attached to each other by means of adhesive bonding or medium-free diffusion bonding. The heat absorption section 12 and the heat dissipation layer 14 are respectively flush with two lateral planes of the carrier body 1.

In the first to fifth embodiments, the heat dissipation layer 14 is selected from a group consisting of porous structure and nanostructure body. The heat dissipation layer 14 has black color, sub-black color or dark color.

Alternatively, the heat dissipation layer 14 is selected from a group consisting of high-radiation ceramic structure and high-hardness ceramic structure.

The heat dissipation structure of handheld device of the present invention is able to effectively dissipate the heat generated in the internal closed space of the handheld device and solve the problem of heat accumulation of the handheld device.

In the heat dissipation structure of handheld device of the present invention, the heat conductor with good thermal conductivity is partially attached to or disposed on the heat absorption section 12 so as to enhance the heat absorption efficiency of the carrier body 1. The black radiation heat dissipation layer 14 is disposed on the heat dissipation section 13 to increase the heat dissipation contact area and promote the heat radiation dissipation efficiency.

The present invention dissipates the heat by way of heat radiation. Heat conduction and convection both necessitate a medium for transferring the heat, while heat radiation can directly transfer the heat without any medium. Accordingly, even in a tiny closed space, the heat can be still transferred to the case of the handheld device for heat exchange between the case and the exterior.

Heat radiation means that the heat is transferred in the form of electromagnetic wave at light speed without any medium. An object can continuously radiate heat and absorb heat radiation from outer side. The ability of radiating heat of an object is related to the surface temperature, color and roughness of the object. According to the relevant application principles, the present invention employs the radiation heat dissipation layer to increase the surface heat dissipation area and promote the natural heat dissipation efficiency. The surface heat radiation intensity of the object is not only related to the temperature, but also related to the properties of the surface. For example, an object with black surface is easier to absorb heat radiation and also easier to radiate heat. Accordingly, the radiation heat dissipation layer of the present invention has black color or the surface of the radiation heat dissipation layer has black color to further enhance the heat radiation efficiency.

In addition, in the case that the carrier body 1 is a thinner plate body, the heat absorption section can further increase the structural strength of the carrier body 1.

The present invention has been described with the above embodiments thereof and it is understood that many changes and modifications in the above embodiments can be carried out without departing from the scope and the spirit of the invention that is intended to be limited only by the appended claims.

What is claimed is:

1. A heat dissipation structure of handheld device, comprising a carrier body, the carrier body having a first receiving space, the first receiving space having a heat absorption section and a heat dissipation section, the heat dissipation section being adjacent to the heat absorption section and formed with a heat dissipation layer, the heat dissipation layer being formed on the heat dissipation section by means of micro-arc oxidation (MAO), plasma electrolytic oxidation (PEO), anodic spark deposition (ASD) or anodic oxidation by spark deposition (ANOF).

2. The heat dissipation structure of handheld device as claimed in claim 1, wherein the carrier body is made of metal or nonmetal material.

3. The heat dissipation structure of handheld device as claimed in claim 1, wherein the carrier body is a stainless steel board body.

4. The heat dissipation structure of handheld device as claimed in claim 1, wherein the heat dissipation layer is made of ceramic material or graphite material.

5. The heat dissipation structure of handheld device as claimed in claim 1, wherein the heat absorption section is a heat conductor with good thermal conductivity, the carrier body is formed with a recess in which the heat absorption section is inlaid, the heat dissipation section being correspondingly disposed on the other side of the recess, the heat dissipation layer being formed on the heat dissipation section.

6. The heat dissipation structure of handheld device as claimed in claim 1, wherein the heat absorption section is a heat conductor with good thermal conductivity, the carrier body being formed with a perforation in which the heat absorption section is inlaid, the heat dissipation section being disposed on the other side corresponding to the heat absorption section, the heat dissipation layer being formed on the heat dissipation section, the heat conductor with good thermal conductivity being selected from a group consisting of copper, aluminum and the likes, the heat absorption section and the heat dissipation layer being respectively flush with two lateral planes of the carrier body.

7. The heat dissipation structure of handheld device as claimed in claim 1, wherein the heat absorption section and the heat dissipation section are heat conductors with good thermal conductivity, the carrier body being formed with a perforation in which the heat absorption section is inlaid, the heat dissipation section being disposed on the other side corresponding to the heat absorption section, the heat dissipation layer being formed on the heat dissipation section, the heat conductors with good thermal conductivity being selected from a group consisting of copper, aluminum and the likes, the heat absorption section and the heat dissipation layer being respectively flush with two lateral planes of the carrier body.

8. The heat dissipation structure of handheld device as claimed in claim 1, wherein the heat dissipation layer is selected from a group consisting of porous structure and nanostructure body.

9. The heat dissipation structure of handheld device as claimed in claim 1, wherein the heat dissipation layer has black color, sub-black color or dark color.

10. The heat dissipation structure of handheld device as claimed in claim 1, wherein the heat dissipation layer is selected from a group consisting of high-radiation ceramic structure and high-hardness ceramic structure.

11. The heat dissipation structure of handheld device as claimed in claim 7, wherein the heat absorption section and the heat dissipation section are attached to each other by means of adhesive bonding or medium-free diffusion bonding.
